(19) United States
(12) Patent Application Publication
(10) Pub. No.: US 2008/0035197 A1
(43) Pub. Date: Feb. 14, 2008

(54) PHOTOACTIVE MATERIALS CONTAINING BULK AND QUANTUM-CONFINED SEMICONDUCTOR STRUCTURES AND OPTOELECTRONIC DEVICES MADE THEREFROM

(76) Inventors: Dmytro Poplavskyy, San Jose, CA (US); Sanjai Sinha, Santa Clara, CA (US); David Jurbergs, Austin, TX (US); Homer Antoniadis, Mountain View, CA (US)

Correspondence Address: FOLEY & LARDNER LLP, 150 EAST GILMAN STREET, P.O. BOX 1497, MADISON, WI, 53701-1497, US

(21) Appl. No.: 11/775,019

(22) Filed: Jul. 9, 2007

Related U.S. Application Data
(60) Provisional application No. 60/819,678, filed on Jul. 10, 2006.

(51) Int. Cl. H01L 31/00; H01C 13/00

(52) U.S. Cl. 136/252; 252/501.1

(57) ABSTRACT

The present invention provides photoactive materials that include quantum-confined semiconductor nanostructures in combination with non-quantum confined and bulk semiconductor structures to enhance or create a type II band offset structure. The photoactive materials are well-suited for use as the photoactive layer in photoactive devices, including photovoltaic devices, photoconductors and photodetectors.

### CROSS-REFERENCE TO RELATED APPLICATIONS

This application claims the benefit of U.S. Provisional Patent Application Ser. No. 60/819,678 filed Jul. 10, 2006, the entire disclosure of which is incorporated by reference.

### FIELD OF THE INVENTION

This invention generally relates to photoactive materials made from a combination of quantum-confined and non-quantum-confined semiconductor structures, to methods for making the photoactive materials, and to devices incorporating the photoactive materials.

### BACKGROUND

Quantum dots are nanometric scale particles, or “nanoparticles” that show quantum confinement effects. In the case of semiconductor nanoparticles having spatial dimensions less than the exciton Bohr radius, the quantum confinement effect manifests itself in the form of size-dependent tunable band gaps and, consequently, tunable light absorption and emission properties.

To exploit the tunable properties, semiconductor quantum dots have been incorporated into devices, such as photovoltaic cells and light emitting diodes, typically in the form of films having suitable electronic and optical coupling with the device and the outside world. For example, U.S. Pat. No. 6,878,871 and U.S. Patent Application Publication Nos. 2005/0126628 and 2004/0095658 describe photovoltaic devices having an active layer that includes inorganic nanostructures, optionally dispersed in a conductive polymer binder. Similarly, U.S. Patent Application Publication No. 2003/0226498 describes semiconductor nanocrystal/conjugated polymer thin films, and U.S. Patent Application Publication No. 2004/0126582 describes materials comprising semiconductor particles embedded in an inorganic or organic matrix. Notably, these references focus on the use of Group II-VI or III-V nanostructures in photovoltaic devices, rather than Group IV nanostructures. This is significant because the conduction and valence bands for bulk Group II-VI and Group III-V semiconductors inherently exhibit a type II band offset. This is not the case for Group IV semiconductors, such as silicon (Si) and germanium (Ge) which exhibit only a very weak type II band offset or a type I band offset, making them substantially more difficult to incorporate into photovoltaic cells. None of the above-cited references acknowledges or addresses the concerns and obstacles presented by the unique band structures of Group IV semiconductors.

### SUMMARY

The present invention provides photoactive materials that utilize a combination of quantum-confined semiconductor nanostructures and non-quantum-confined semiconductor structures. The use of a combination of quantum-confined semiconductor nanostructures and non-quantum-confined structures makes it possible to tune the band alignment of the semiconductor materials, resulting in the enhancement or creation of a type II band alignment. In some instances, the non-quantum-confined structures are nanostructures, while in other instances the non-quantum-confined structures are layers of bulk semiconductor material. The photovoltaic materials are well-suited for use as the active layer in photoactive devices, including photovoltaic devices, photoconductors and photodetectors. However, the photoactive materials may also be used in light emitting devices, such as light emitting diodes.

The quantum-confined nanostructures may be Group IV semiconductor-containing nanostructures including, but not limited to, Group IV nanocrystals and nanowires. The nanostructures may be composed of Group IV semiconductor alloys (e.g., alloys of Si and Ge (i.e., “SiGe alloys”)); or they may be core/shell nanostructures wherein the core, the shell, or the core and the shell include, or are entirely composed of, a Group IV element. Suitable examples of core/shell nanostructures include nanoparticles or nanowires having a Si core and a Ge shell (“SiGe core/shell nanostructures”) and nanoparticles or nanowires having a Ge core and a Si shell (“GeSi core/shell nanostructures”). In some embodiments only the core of the core/shell nanostructures is quantum-confined, while in other embodiments, both the core and shell of the core/shell nanostructures are quantum-confined. The quantum-confined nanostructures may also be hydrogen-terminated or capped with organic moieties which passivate the surface of the nanostructures and/or facilitate their incorporation into a matrix. The moieties may be present as a result of the process used to make the nanostructures, or they may be attached to the nanostructures in a separate processing step, after the nanostructures have been formed.

The quantum-confined nanostructures and the non-quantum-confined nanostructures may be single-crystalline, polycrystalline, amorphous, or a combination thereof. The non-quantum-confined structures may be made of the same semiconductor material as the quantum-confined nanostructures, differing only in size distribution and/or structure (i.e., single crystalline, polycrystalline or amorphous structures), or they may be made of different semiconductors. Thus, in some embodiments the non-quantum-confined structures are single crystal structures and the quantum-confined structures are single crystal structures (i.e., “nanocrystals”). In other embodiments, the non-quantum-confined structures are amorphous or polycrystalline structures and the quantum-confined nanostructures are single crystal nanostructures.

The quantum-confined nanostructures and the non-quantum-confined structures may be contained in a single layer, such that they provide a bulk heterojunction. Alternatively, the quantum-confined nanostructures and the non-quantum-confined structures may be contained in separate sublayers of the photoactive material. This may be the case, for example, when the non-quantum-confined structure takes the form of a layer of bulk semiconductor material. Within the photoactive materials, the quantum-confined nanostructures and/or the non-quantum-confined structures may be dispersed in an organic matrix, such as a polymer matrix, or in an inorganic matrix. When a polymer matrix is present, the polymer may be a non-conducting or an electrically conducting polymer.

Photoactive devices made from the photoactive materials generally include the photoactive material in electrical communication with a first electrode and a second electrode. Other layers commonly employed in photoactive devices (e.g., barrier layers, blocking layers, recombination layers, insulating layers, protective casings, etc.) may also be incorporated into the devices.

Further objects, features and advantages of the invention will be apparent from the following detailed description when taken in conjunction with the accompanying drawings.

### BRIEF DESCRIPTION OF THE DRAWINGS

FIG. 1 is an energy band diagram showing the conduction and valence band alignment for (a) bulk crystalline Si (left side) and bulk crystalline Ge (right side); and (b) bulk crystalline Si (left side) and quantum-confined crystalline Ge (right side).

FIG. 2 is an energy band diagram showing the conduction and valence band alignment for (a) bulk amorphous Si (left side) and bulk crystalline Si (right side); and (b) bulk amorphous Si (left side) and quantum-confined crystalline Si (right side).

FIG. 3 is an energy band diagram showing the conduction and valence band alignment for (a) bulk amorphous Si (left side) and bulk crystalline Ge (right side); and (b) bulk amorphous Si (left side) and quantum-confined crystalline Ge (right side).

FIG. 4 is an energy band diagram showing the conduction and valence band alignment for (a) bulk crystalline Si (left side) and bulk crystalline α-Sn (right side); and (b) bulk crystalline Si (left side) and quantum-confined crystalline α-Sn (right side).

FIG. 5 is an energyband diagram showing the conduction and valence band alignment for (a) bulk crystalline Ge (left side) and bulk crystalline α-Sn (right side); and (b) bulk crystalline Ge (left side) and quantum-confined crystalline α-Sn (right side).

FIG. 6 shows a schematic cross-sectional view of a photovoltaic device in accordance with the present invention.

### DETAILED DESCRIPTION

The present invention provides photoactive materials that utilize a combination of quantum-confined semiconductor nanostructures and non-quantum-confined semiconductor structures to enhance or create a type II band offset structure. In some instances, the non-quantum-confined structures are nanostructures, while in other instances the non-quantum-confined structures are layers of bulk semiconductor material. The photoactive materials are well-suited for use as the active layer in photoactive devices (i.e., devices that convert electromagnetic radiation into electrical energy), including photovoltaic devices, photoconductors and photodetectors.

As used herein, the phase “quantum-confined semiconductor nanostructure” refers to any semiconductor nanostructure having dimensions small enough to produce size-dependent band gaps and, consequently, size-dependent light absorption and emission properties. The quantum confinement may be in two dimensions (e.g., quantum-confined nanowires) or in three dimensions (e.g., quantum-confined nanoparticles). The terms “non-quantum-confined structures” and “bulk semiconductor” refer to semiconductor structures whose light absorption and emission properties reflect the bulk properties of the semiconductor materials from which they are constructed. The quantum-confined semiconductor nanostructures of the photoactive materials are selected to produce or enhance a type II band offset with respect to the non-quantum-confined semiconductor materials, where two materials have a “type II band offset” if the conduction band or valence band, but not both, of one material is within the bandgap of the other material.

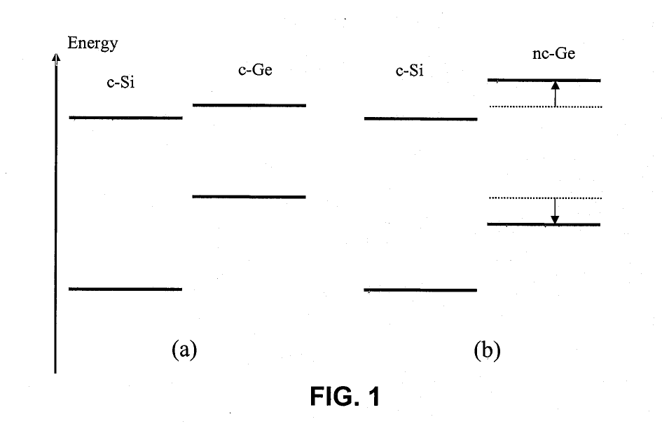

The quantum-confined semiconductor nanostructures have a higher conduction band energy and a lower valence band energy than their non-quantum-confined counterparts. Thus, the use of quantum-confined nanostructures, rather than the corresponding non-quantum-confined nanostructures, results in an enhanced conduction band offset and an enhanced open voltage, resulting from the lowering of the valence band energy. This is illustrated in FIGS. 1(a) and (b). FIG. 1(a) is an energy band diagram showing the conduction and valence band alignment for bulk (i.e., non-quantum-confined) crystalline Si and Ge. As shown in the figure, the valence band of bulk Si is about 500 meV lower than that of bulk Ge and the conduction band of bulk Si lies only 50 meV below that of bulk Ge. Such a band alignment is poorly suited to provide efficient charge separation at the Si/Ge interface, as required for photovoltaic cell operation. FIG. 1(b) is an energy band diagram showing the conduction and valence band alignment for bulk crystalline Si and quantum-confined nanocrystalline Ge. As shown in this figure, the use of quantum-confined Ge nanocrystals enhances the conduction band offset and reduces the valence band offset, resulting in a band alignment that is well-suited for use in a photovoltaic cell.

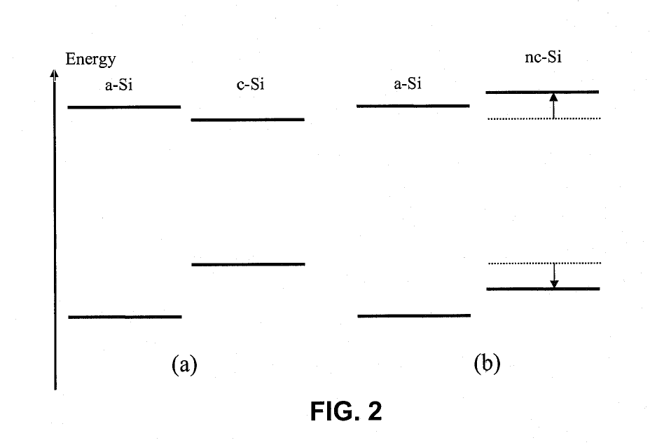

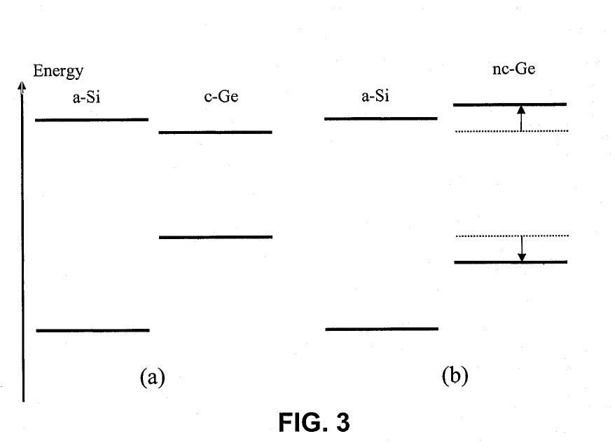

In other cases, the quantum-confined semiconductor nanostructures are made from a semiconductor material characterized in that, as a quantum-confined material, it exhibits a type II band offset with respect to the non-quantum-confined semiconductor structures, but as a bulk material it exhibits a type I band offset with respect to the non-quantum-confined semiconductor structures, wherein two materials have a “type I band offset” if the conduction band and valence band of one material are both within the bandgap of the other material (see, for example, FIG. 2(a)). In such cases, the careful selection of a combination of quantum-confined semiconductor nanostructures and non-quantum-confined semiconductor structures makes it possible to produce a photoactive layer for a photovoltaic cell from a material system that would not otherwise provide a type II band offset. This is particularly important for Group IV semiconductor-based photoactive devices, due to the energy band alignment of materials such as Si and Ge, as illustrated in FIGS. 2(a) and (b) and FIGS. 3(a) and (b). FIG. 2(a) is an energy band diagram showing the conduction band and valence band alignment for bulk amorphous Si and bulk crystalline Si. As shown in this figure, the two materials exhibit a type I band offset. In contrast, FIG. 2(b) shows that by replacing the bulk crystalline Si with quantum-confined nanocrystalline Si, a type II band offset is produced. Similarly, the energy band diagram of FIGS. 3(a) and (b) shows that bulk amorphous Si and bulk crystalline Ge exhibit a type I band offset, while bulk amorphous Si and quantum-confined nanocrystalline Ge exhibit a type II band offset.

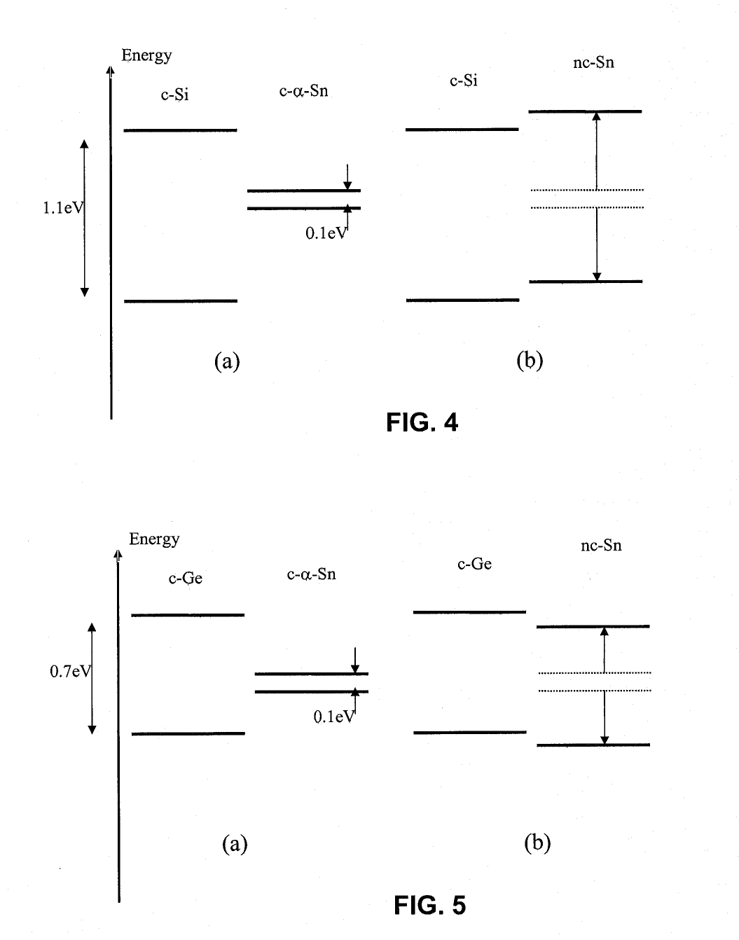

FIGS. 4 and 5 show other examples of systems where the use of quantum-confined semiconductor nanostructures makes it possible to produce a photoactive layer for a photovoltaic cell from a material system that would not otherwise provide a type II band offset. FIG. 4(a) is an energy band diagram showing the conduction band and valence band alignment for bulk crystalline Si and bulk crystalline α-Sn. As shown in this figure, the two materials exhibit a type I band offset. In contrast, FIG. 4(b) shows that by replacing the bulk crystalline α-Sn with strongly quantum-confined nanocrystalline α-Sn, a type II band offset is produced. Similarly, the energy band diagrams of FIGS. 5(a) and (b) show that bulk crystalline Ge and bulk crystalline α-Sn exhibit a type I band offset, while bulk crystalline Ge and strongly quantum-confined nanocrystalline α-Sn exhibit a type II band offset. In order to achieve the strong quantum confinement effects for α-Sn illustrated in FIGS. 4 and 5, the α-Sn nanostructures desirably have one or more dimensions of less than 5 nm, desirably less than 1 nm, and more desirably less than 0.5 nm.

Quantum-Confined Semiconductor Nanostructures:

The quantum-confined semiconductor nanostructures in the present photoactive materials are nanostructures having sufficiently small sizes to provide them with quantum confinement effects in at least two dimensions. Thus, the maximum size of the quantum-confined semiconductor nanostructures will depend on the particular materials from which they are made. The nanostructures may be generally spherical, as in the case of semiconductor nanocrystals, or elongated, as in the case of semiconductor nanowires or nanorods. In some instances the elongated nanostructures will have an aspect ratio (i.e., the ratio of the length of the nanostructure to the width of the nanostructure) of at least 2, at least ten, at least 100, or even at least 1000. In other cases, the nanostructures may take on more complex geometries, including branched geometries or shapes, such as cubic, pyramidal, double square pyramidal, or cubeoctahedral. The nanostructures within a given population of quantum-confined nanostructures may have a variety of shapes and a given population of quantum-confined nanostructures may include nanostructures of different sizes.

In a preferred embodiment of the invention, the quantum-confined semiconductor nanostructures are Group IV semiconductor nanostructures. Group IV nanostructures include, but are not limited to, Si nanocrystals and nanowires, Ge nanocrystals and nanowires, Sn nanocrystals and nanowires, SiGe alloy nanocrystals and nanowires and nanocrystals and nanowires comprising alloys of tin and Si and/or Ge. The nanostructures may be nanoparticles or nanowires that include a core and an inorganic shell. Such nanoparticles and nanowires shall be referred to as “core/shell nanoparticles” and “core/shell nanowires,” respectively. The core/shell nanostructures of the present invention may include a Group IV semiconductor in their shell, in their core, or in both their core and their shell. For example, the core/shell nanostructures may include a Si core and a Ge shell, or a Ge shell and a Si core.

In some embodiments only the core of the core/shell nanoparticles or nanowires is quantum-confined. In these embodiments, the shell acts as a bulk semiconductor material which forms a type II band offset with respect to the quantum-confined core. Thus, such core/shell nanostructures include both a quantum-confined nanostructure and a non-quantum-confined nanostructure, whereby electrons and holes are separated at the core/shell interface and one type of carrier travels from the core to the shell and the other type of carrier tunnels from core to core. Such core/shell nanoparticles or nanowires may be embedded in a bulk semiconductor matrix to enhance carrier transport. This bulk semiconductor matrix may be made from the same semiconductor material as the shell of the core/shell nanostructure.

In other embodiments, both the core and the shell of the core/shell nanostructures are quantum-confined. In these embodiments the entire core/shell nanostructure is referred to as a quantum-confined nanostructure.

For the Si nanostructures, the maximum nanostructure dimension for quantum confinement is about 10 nm. Within this range, the inventors have discovered that Si nanostructures (e.g., nanocrystals or nanowires) having maximum dimensions in two or three dimensions of about 1 to 10 nm are particularly well-suited for use in the present photoactive materials. For the Ge nanostructures, the maximum nanostructure dimension for quantum confinement is about 35 nm. Within this range, the inventors have discovered that Ge nanostructures (e.g., nanocrystals or nanowires) having maximum dimensions in two or three dimensions of about 1 to 35 nm are particularly well-suited for use in the present photoactive materials. For the Sn nanostructures, the maximum nanostructure dimension for quantum confinement is about 40 nm. The quantum-confined Sn nanostructures may have one or more dimensions of no more than about 30 nm, no more than about 20 nm, no more than about 10 nm, no more than about 5 nm, or even more than about 1 nm. Within these ranges, the inventors have discovered that Sn nanostructures (e.g., nanocrystals) having maximum dimensions of about 1 to 20 nm, and preferably about 1 to 15 nm, are particularly well-suited for use in the present photoactive materials. For the SiGe alloy nanostructures, the maximum nanostructure dimension for quantum confinement is about 35 nm. Within this range, the inventors have discovered that SiGe alloy nanostructures (e.g., nanocrystals) having maximum dimensions of about 1 to 35 nm are particularly well-suited for use in the present photoactive materials.

In some embodiments, the quantum-confined semiconductor nanostructures may be hydrogen-terminated or capped by organic molecules, which are bound to, or otherwise associated with, the surface of the nanostructures. These organic molecules may passivate the nanostructures and/or facilitate the incorporation of the nanostructures into a solvent or polymer matrix. Examples of suitable passivating organic ligands include, but are not limited to, perfluoroalkenes, perfluoroalkene-sulfonic acids, alkenes, alkynes, carboxylic acids, nonionic surfactants, and alcohols. Specific examples of capping agents for inorganic nanoparticles are described in U.S. Pat. No. 6,846,565, the entire disclosure of which is incorporated herein by reference. The capping ligands may be associated with the surface of the nanostructures during the formation of the nanostructures, or they may be associated with the nanostructures in a separate processing step, after nanostructure formation.

The quantum-confined nanostructures (e.g., nanocrystals) in the material may have a polydisperse or a substantially monodisperse size distribution, provided the size-distribution remains in the quantum-confined regime. As used herein, the term “substantially monodisperse” refers to a plurality of nanostructures which deviate by less than 20% root-mean-square (rms) in diameter, more preferably less than 10% rms, and most preferably less than 5% rms, where the diameter of a nanostructure refers to the largest cross-sectional diameter of the nanostructure. The term polydisperse refers to a plurality of nanostructures having a size distribution that is broader than monodisperse. For example, a plurality of nanostructures which deviate by at least 25%, 30%, or 35%, root-mean-square (rms) in diameter would be a polydisperse collection of nanostructures. One advantage of using a population of quantum-confined nanostructures having a polydisperse size distribution is that different nanostructures in the population will be capable of absorbing light of different wavelengths. This may be particularly desirable in applications, such as photovoltaic cells, wherein absorption efficiency is important.

Methods for synthesizing semiconductor nanostructures include plasma synthesis, laser pyrolysis, thermal pyrolysis, and wet chemical synthesis. Suitable methods for forming quantum-confined (and non-quantum-confined) nanostructures comprising Group IV semiconductors may be found in U.S. Pat. No. 4,994,107, U.S. Pat. No. 5,695,617, U.S. Pat. No. 5,850,064, U.S. Pat. No. 6,585,947, U.S. Pat. No. 6,855,204, U.S. Pat. No. 6,723,606, U.S. Pat. No. 6,586,785, U.S. Patent Application Publication Nos. 2004/0229447, 2006/0042414, 2006/0051505, and WO0114250, the entire disclosures of which are incorporated herein by reference.

Non-Quantum-Confined (or “bulk”) Semiconductor Structures:

The non-quantum-confined semiconductor structures in the present photoactive materials are structures having dimensions that provide them with bulk light absorption and emission properties. Thus, the minimum size of the non-quantum-confined semiconductor structures will depend on the particular materials from which they are made. The non-quantum-confined structures may be provided in the form of bulk particles or nanostructures, or may be provided in the form of a layer of bulk material within the active layer. As illustrated in FIGS. 2 and 3, the semiconductors that make up the non-quantum-confined semiconductor structures may be the same as, or different from, the semiconductors that make up the quantum-confined nanostructures, although the specific structure of the semiconductors (e.g., single crystalline vs. polycrystalline vs. amorphous) may be different.

As used herein, the term nanostructure is used broadly to refer to a particle having a diameter in at least one dimension (e.g., length, width or height) of up to about 500 nm. For some nanostructures at least two, and in some cases all three, dimensions of the nanostructure will fall into the above-referenced size limitations. Of course, since the properties of the non-quantum-confined structures are not size-dependent, larger particles may also be used. As in the case of the quantum-confined nanostructures, the non-quantum-confined nanostructures may be generally spherical, as in the case of semiconductor nanocrystals, or elongated, as in the case of semiconductor nanowires and nanorods, or may take on more complex geometries. The nanostructures within a given population of non-quantum-confined nanostructures may have a variety of shapes and a given population of non-quantum-confined nanostructures may include nanostructures of different sizes. However, for ease of processability, the non-quantum-confined nanostructures may have average dimensions of no more than about 200 nm and desirably no more than about 100 nm.

For the Si nanostructures, the minimum nanostructure dimension for bulk behavior is just above about 10 nm. For example, non-quantum-confined Si nanostructures may have dimensions of 11 nm or greater, 15 nm or greater, 20 nm or greater, or 30 nm or greater. For the Ge nanostructures, the minimum nanostructure dimension for bulk behavior is just above about 35 nm. For example, non-quantum-confined Ge nanostructures may have dimensions of 36 nm or greater, 40 nm or greater, or 45 nm or greater. For the Sn nanostructures, the minimum nanostructure dimension for bulk behavior is just above about 40 nm. For example, non-quantum-confined Sn nanostructures may have dimensions of 41 nm or greater, 45 nm or greater, or 50 nm. For the SiGe alloy nanostructures, the minimum nanostructure dimension for bulk behavior is just above about 35 nm. For example, non-quantum-confined SiGe nanostructures may have dimensions of 36 nm or greater, 40 nm or greater, or 45 nm or greater.

In a preferred embodiment of the invention, the non-quantum-confined semiconductor nanostructures are Group IV semiconductor nanostructures, including, but not limited to, Si nanocrystals and nanowires, Ge nanocrystals and nanowires, Sn nanocrystals and nanowires, SiGe alloy nanocrystals and nanowires, and nanocrystals and nanowires comprising alloys of tin and Si and/or Ge.

Like the quantum-confined semiconductor nanostructures, the non-quantum-confined semiconductor nanostructures may be hydrogen-terminated or capped by organic molecules, which are bound to, or otherwise associated with, the surface of the nanostructures, as described above with respect to the quantum-confined nanostructures. In addition, the non-quantum-confined nanostructures (e.g., nanocrystals) in the material may have a polydisperse or a substantially monodisperse size distribution (as defined above), provided the size-distribution remains in the bulk regime. The semiconductors of the non-quantum-confined nanostructures may be crystalline, polycrystalline or amorphous semiconductors.

The non-quantum-confined nanostructures may be grown from, and therefore in direct contact with, a semiconductor layer in an optoelectronic device or they may be “free-standing” in that they are not in direct contact with layers, other than the active layer, of a photoactive device.

As an alternative to (or in addition to) bulk particles or nanostructures, the non-quantum-confined semiconductor structures may be layers of bulk material within a photoactive region. For example, the non-quantum-confined semiconductor structures may be one or more layers of amorphous semiconductor material (e.g., amorphous Si) or a layer of polycrystalline semiconductor layer (e.g., polycrystalline Si). The semiconductors of the bulk layers may be crystalline, polycrystalline or amorphous semiconductors. In preferred embodiments, the layers of bulk material are made partially or entirely from Group IV semiconductors, including Si, Ge, SiGe alloys, Sn and alloys of Sn with Si and/or Ge.

The Photoactive Material:

If a layer of bulk semiconductor is used as the non-quantum-confined semiconductor structure, the photoactive material may include quantum-confined nanostructures embedded within the bulk semiconductor layer. This could be accomplished by codepositing quantum-confined nanostructures with the bulk material to form a single layer. For example, quantum-confined Ge nanocrystals could be codeposited within an amorphous Si matrix. Codeposition could be carried out from the gas phase or by seeding the quantum-confined nanocrystals with the overgrowth of an amorphous semiconductor matrix around the seeded nanocrystals. Alternatively, the photoactive material could include at least two sublayers—one sublayer composed of the bulk semiconductor material and another sublayer containing the quantum-confined nanostructures.

If bulk particles or nanostructures are used as the non-quantum-confined structures, the quantum-confined nanostructures and non-quantum-confined structures may be mixed together in a single layer, or may be contained within separate sublayers of the photoactive material. The sublayers may be in direct contact, such that a heterojunction is formed between the sublayers. In some embodiments, the photoactive materials include three or more sublayers, which may provide a series of (i.e., two or more) heterojunctions. Different sublayers in a multilayered photoactive material may contain different populations (in terms of size distribution and/or chemical composition) of quantum-confined and non-quantum-confined nanostructures. In some embodiments the compositions and/or size distributions of the quantum-confined nanostructures in different sublayers may be different, such that different sublayers have different light absorbing characteristics. For example, the sublayers may be arranged with an ordered distribution, such that the quantum-confined semiconductor nanostructures having the highest bandgaps are near one surface of a multilayered photoactive material and the quantum-confined semiconductor nanostructures having the lowest bandgaps are near the opposing surface of a multilayered photoactive material.

Within the photoactive material, the quantum-confined nanostructures and the non-quantum-confined structures may be in the form of a neat mixture, that is, a mixture without any matrix or binder, other than any matrix formed by the quantum-confined and/or non-quantum-confined nanostructures themselves. Alternatively, quantum-confined nanostructures and/or non-quantum-confined nanostructures (whether in a single layer or in separate sublayers) may be dispersed in a polymer matrix or binder.

In some embodiments, quantum-confined and/or non-quantum-confined nanostructures (whether in a single layer or in separate sublayers) in the photoactive material are thermally treated to at least partially fuse, sinter or melt the nanostructures together to provide better contact between neighboring nanostructures in order to improve charge transport and reduce trap density. Thermal treatment may also help to passivate any surface trap states and/or to remove surface moities, resulting in better packing and better charge transport properties. However, with respect to quantum-confined nanostructures, it is important to control the thermal treatment temperature accurately to prevent the quantum-confined nanostructures from melting together and losing the effects of quantum confinement that are required for the correct energy band alignment between the quantum-confined nanostructures and the non-quantum-confined structures, and, in the case of amorphous structures, to prevent re-crystallization that may occur at elevated temperatures. Thermal treatment may be carried out in situ as the various sublayers are deposited, or after each sublayer is deposited, and may be performed separately for different sublayers of a photoactive material or may be performed on all sublayers simultaneously.

For photoactive materials that contain either elongated quantum-confined nanostructures, elongated non-quantum-confined nanostructures, or both, such nanostructures may be oriented randomly, or may be oriented non-randomly with a primary alignment direction perpendicular to the surface of the material. A population of elongated nanostructures is “non-randomly oriented with a primary alignment direction perpendicular to the surface of the material” if significantly more (e.g., ≧25% or ≧10% more) of the elongated nanostructures are aligned in a perpendicular orientation relative to a completely random distribution of nanostructures.

Photoactive Devices:

The photoactive materials may be used in a variety of devices which convert electromagnetic radiation into an electric signal. Such devices include photovoltaic cells, photoconverters, and photodetectors. Generally, these devices will include the photoactive material electrically coupled to two or more electrodes. Each layer in the device may be quite thin, e.g., having a thickness of no more than about 5000 nm, no more than about 2000 nm, or even no more than about 1000 nm. However, layers having greater thicknesses may also be employed. When the photoactive material is used in a photovoltaic cell, the device may further include a power consuming device, or load, (e.g., a lamp, a computer, etc.) which is in electrical communication with, and powered by, one or more photovoltaic cells. When the photoactive material is used in a photoconductor or photodetector, the device further includes a current detector coupled to the photoactive material.

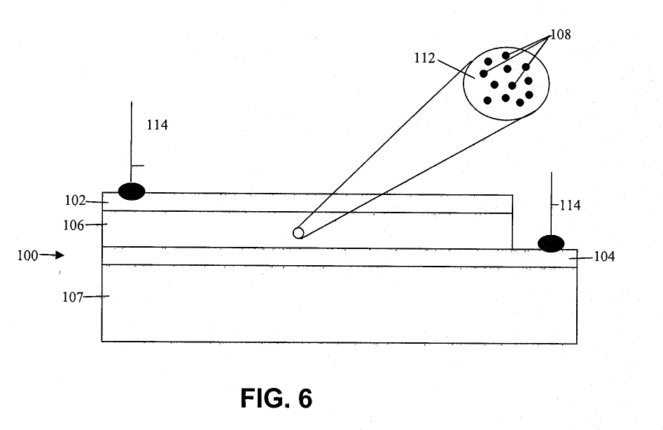

FIG. 6 shows a schematic diagram of a cross-sectional view of one example of a simple photovoltaic device 100 in accordance with the present invention. The device of FIG. 6, includes a first electrode 102, a second electrode 104 and a photoactive material 106, disposed between, and in direct contact with, the first and second electrodes. Although the photoactive material is in direct contact with the electrodes in the depicted embodiment, it is necessary only that the photoactive material and the electrodes be in electrical communication, that is, connected to allow for electrical current flow. Thus, direct contact between the electrodes and the active layer is not necessary and other layers, such as electron injecting, hole injecting, blocking layers or recombination layers, may be disposed between the electrodes and the photoactive material. As shown in the figure, one electrode may be supported by an underlying substrate 107. As shown in the inset of FIG. 6, the photoactive material 106 is a single layer material containing quantum-confined semiconductor nanostructures 108 (e.g., Ge nanocrystals) dispersed in a bulk semiconductor matrix 112 (e.g., an amorphous Si layer). At least one of the two electrodes and, optionally, the substrate, is desirably transparent, such that it allows light to reach the photoactive material. In addition, the electrodes and substrate are desirably thin and flexible, such that the entire device structure provides a thin film photovoltaic cell. Transparent metal oxides, such as tin oxide or indium tin oxide (ITO) on a flexible, transparent polymer substrate, is an example of a transparent, flexible electrode material. The electrodes are in electrical communication (e.g., via wires 114) with some type of load, such as an external circuit or a power consuming device (not shown).

Method of Making a Photovoltaic Device:

A photovoltaic device may be fabricated from the photoactive materials as follows. A substrate with a bottom transparent electrode (e.g., ITO on a polymer film or glass) is cleaned and a thin buffer layer (e.g., about 30-100 nm) of PEDOT:PSS is spin-coated onto the electrode. Organic or inorganic buffer layers other than PEDOT:PSS may also be used, including buffer layers that help to planarize the substrate surface and/or prepare the substrate surface for optimization of charge extraction during the operation of the photovoltaic device. A photoactive layer comprising a blend of bulk Si nanocrystals and quantum-confined Ge nanocrystals is formed over the PEDOT:PSS by spin coating a solution of the blend in chloroform. (Other suitable methods for forming the photoactive layer include, but are not limited to, plasma deposition, spray coating, and ink-jet or screen printing.) Finally, 200 nm of aluminum top electrode is deposited over the photoactive layer.

For the purposes of this disclosure and unless otherwise specified, “a” or “an” means “one or more.” All patents, applications, references and publications cited herein are incorporated by reference in their entirety to the same extent as if they were individually incorporated by reference.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member.

While the principles of this invention have been described in connection with specific embodiments, it should be understood clearly that these descriptions are made only by way of example and are not intended to limit the scope of the invention.

What is claimed is:

1. A photoactive material comprising a plurality of quantum-confined semiconductor nanostructures and a plurality of non-quantum-confined semiconductor structures, wherein the plurality of quantum-confined semiconductor nanostructures and the plurality of non-quantum confined semiconductor structures have a type II band offset.

2. The photoactive material of claim 1, wherein the plurality of quantum-confined semiconductor nanostructures are made from a semiconductor material and further wherein the semiconductor material exhibits a type II band offset with respect to the plurality of non-quantum-confined semiconductor structures as a quantum-confined material, but exhibits a type I band offset with respect to the plurality of non-quantum-confined semiconductor structures as a bulk material.

3. The photoactive material of claim 1, wherein the plurality of quantum-confined semiconductor nanostructures and the plurality of non-quantum-confined semiconductor structures comprise Group IV semiconductors.

4. The photoactive material of claim 3, wherein the plurality of quantum-confined semiconductor nanostructures are germanium nanostructures, and the plurality of non-quantum-confined semiconductor structures comprise one of amorphous silicon, single-crystalline silicon, and polycrystalline silicon.

5. The photoactive material of claim 4, wherein the germanium nanostructures have dimensions of no more than about 35 nm, and the plurality of non-quantum-confined semiconductor structures have at least one dimension no greater than 10 nm.

6. The photoactive material of claim 3, wherein the plurality of quantum-confined semiconductor nanostructures are tin nanostructures, and the plurality of non-quantum-confined semiconductor structures comprise one of amorphous silicon, single-crystalline silicon, polycrystalline silicon, amorphous germanium, single-crystalline germanium, and polycrystalline germanium.

7. The photoactive material of claim 1, wherein the plurality of quantum-confined semiconductor nanostructures are silicon nanocrystals and the plurality of non-quantum-confined semiconductor structures are amorphous silicon.

8. The photoactive material of claim 1, wherein the plurality of quantum-confined semiconductor nanostructures and the plurality of non-quantum-confined semiconductor structures are amorphous structures.

9. The photoactive material of claim 1, wherein the plurality of quantum-confined semiconductor nanostructures and the plurality of non-quantum-confined semiconductor structures are contained in a single layer.

10. The photoactive material of claim 1, wherein the at least one of the plurality of quantum-confined nanostructures and the plurality of non-quantum-confined semiconductor structures include at least two elements selected from the group consisting of Si, Ge, and Sn.

11. The photoactive material of claim 1, wherein the photoactive material comprises a first sublayer and a second sublayer adjacent to the first sublayer, wherein the first sublayer includes the plurality of quantum-confined semiconductor nanostructures, and the second sublayer includes the plurality of non-quantum-confined semiconductor structures.

12. The photoactive material of claim 1, wherein the plurality of quantum-confined semiconductor nanostructures are single crystalline silicon nanoparticles having dimensions of no greater than about 10 nm, and the plurality of non-quantum-confined semiconductor structures are amorphous silicon nanoparticles.

13. The photoactive material of claim 1, wherein the plurality of quantum-confined semiconductor nanostructures are single crystalline silicon nanoparticles having dimensions of no greater than about 10 nm, and the plurality of non-quantum-confined semiconductor structures are amorphous germanium nanoparticles.

14. An optoelectronic device comprising:
(a) a first electrode;
(b) a second electrode; and
(c) a photoactive layer, the photoactive layer comprising a plurality of quantum-confined semiconductor nanostructures and a plurality of non-quantum-confined semiconductor structures having a type II band offset in electrical communication with the first electrode and the second electrode.

15. A photoactive material comprising a first sublayer and a second sublayer adjacent to the first sublayer, wherein the first sublayer includes a plurality of quantum-confined semiconductor nanostructures, and the second sublayer includes a bulk semiconductor, wherein the plurality of quantum-confined nanostructures and the bulk semiconductor have a type II band offset.

16. The photoactive material of claim 15, wherein the plurality of quantum-confined semiconductor nanostructures are made from a semiconductor material characterized in that, as a quantum-confined material it exhibits a type II band offset with respect to the bulk semiconductor, but as a bulk material it exhibits a type I band offset with respect to the bulk semiconductor.

17. The photoactive material of claim 15, wherein the plurality of quantum-confined semiconductor nanostructures and the bulk semiconductor comprise Group IV semiconductors.

18. The photoactive material of claim 17, wherein the quantum-confined semiconductor nanostructures are germanium nanostructures, and the bulk semiconductor comprises one of amorphous silicon, single-crystalline silicon, and polycrystalline silicon.

19. The photoactive material of claim 17, wherein the plurality of quantum-confined semiconductor nanostructures are tin nanostructures, and the bulk semiconductor comprises one of amorphous silicon, single-crystalline silicon, polycrystalline silicon, amorphous germanium, single-crystalline germanium, and polycrystalline germanium.

20. The photoactive material of claim 15, wherein the plurality of quantum-confined semiconductor nanostructures and the bulk semiconductor are made from the same semiconductor material.

21. The photoactive material of claim 20, wherein the plurality of quantum-confined semiconductor nanostructures are silicon nanocrystals and the bulk semiconductor comprises amorphous silicon.

22. The photoactive material of claim 15, wherein the plurality of quantum-confined nanostructures include at least two elements selected from the group consisting of Si, Ge and Sn.

23. A photoactive material comprising a plurality of quantum-confined semiconductor nanostructures embedded in a layer of bulk semiconductor, wherein the plurality of quantum-confined semiconductor nanostructures and the layer of bulk semiconductor have a type II band offset.

24. The photoactive material of claim 23, wherein the plurality of quantum-confined semiconductor nanostructures are made from a semiconductor material, and further wherein the semiconductor material exhibits a type II band offset with respect to the bulk semiconductor as a quantum-confined material, but exhibits a type I band offset with respect to the bulk semiconductor as a bulk material.
